(19) United States
(12) Patent Application Publication
(10) Pub. No.: US 2006/0275654 A1
(43) Pub. Date: Dec. 7, 2006

(54) Battery pressure relief valve

(75) Inventors: John Willard Hooke, Ozark, MO (US); Frank Albert Fleming, Ozark, MO (US); Christopher S. Mauhar, Maple Grove, MN (US)

Correspondence Address: THOMPSON COBURN, LLP, ONE US BANK PLAZA, SUITE 3500, ST LOUIS, MO, 63101, US

(73) Assignee: NorthStar Bettery Company, LLC

(21) Appl. No.: 11/145,706

(22) Filed: Jun. 6, 2005

(51) Int. Cl. H01M 2/12; H01L 29/04

(52) U.S. Cl. 429/89; 257/61

(57) ABSTRACT

A battery pressure relief valve has a center stem that extends downwardly through and is secured to a fill tube opening of the battery to securely hold the valve to the battery. A circular top panel is provided on the upper end of the stem. The top panel extends over the fill tube opening. A cylindrical sidewall extends downwardly from the top panel periphery and around the fill tube. The cylindrical sidewall provides a resilient seal around the fill tube that seals the battery interior from the exterior environment of the battery. The sidewall flexes radially outwardly when subjected to fluid pressure from the batter interior, enabling the safe venting of the fluid pressure, and reseals around the fill tube when the pressure is relieved.

### BACKGROUND OF THE INVENTION

(1) Field of the Invention

The present invention pertains to a battery pressure relief valve used on a lead cell battery. In particular, the present invention pertains to a battery pressure relief valve that is used on a valve-regulated lead-acid battery. The valve has a center stem that extends downwardly into a fill tube opening of the battery to securely hold the valve to the battery. A circular top panel on the upper end of the stem extends over the fill tube opening. A cylindrical sidewall extends downwardly from the top panel periphery and engages in sealing engagement around the fill tube to thereby seal the fill tube opening from the exterior environment of the battery. The cylindrical sidewall provides a resilient seal around the fill tube that flexes radially outwardly when subjected to fluid pressure from the battery interior, enabling the safe venting of the fluid pressure. The sidewall returns to its sealing engagement around the fill tube when the pressure is relieved.

(2) Description of the Related Art

Valve-regulated lead-acid batteries (VRLA) are typically small and lightweight batteries that have high performance characteristics and are very economical to use. VRLA batteries have a number of applications. They are often used as a backup power source for computers, servers, and other office and factory automation equipment. They are also used in security systems and building fire alarms, emergency lighting systems, in electric tools, and in electrically operated vehicles such as electric automobiles and electric wheelchairs.

A VRLA battery employs absorbed glass mat (AGM) technology in its construction, eliminating the need to periodically fill the battery with water. This enables the battery casing to be sealed, except for the fill openings on the battery casing that enable acid electrolyte to be supplied to the battery interior when the battery is manufactured. Thus, a VRLA battery is basically maintenance free.

A typical lead-acid battery has a fill opening for every 2 volt cell in the interior of the battery casing. The valve that closes each electrolyte fill opening of the battery casing is a one-way valve that is typically constructed of a rubber-like material, for example, neoprene. The battery casing, including the fill tubes surrounding the battery fill openings, is typically constructed of a plastic material, for example acrylonitrile-butadiene-styrene (ABS) or polypropylene (PP).

FIG. 1 is a simple schematic representation of the conventional construction of a prior art battery pressure relief valve 12. The valve 12 is shown positioned on a fill tube 14 that surrounds a fill opening 16 in the top wall 18 of a battery casing. The prior art valve 12 is basically a flexible resilient cap that fits over the battery fill tube 14 and closes the fill tube opening 16. The cap has a circular top wall 22 and a cylindrical sidewall 24. The sidewall 24 is dimensioned to fit in a tight sealing fit around the fill tube 14. A valve retainer/top cover 26 of the battery casing is typically secured to the casing top wall 18 covering over the valve.

The cylindrical sidewall 24 of the battery pressure relief valve 12 seals around the fill tube 14 to seal the battery interior from the exterior atmosphere of the battery. The valve 12 prevents oxygen in the atmosphere from entering into the battery interior and reacting with the material of the negative plates.

When VRLA batteries are not in use for long periods of time and the battery is not being discharged or charged, the oxygen inside the battery has a tendency to recombine with the material of the negative plates. The combining of the oxygen with the negative plates creates a vacuum pressure inside the battery casing. The seal around the battery fill tube 14 provided by the pressure relief valve 12 prevents the vacuum created in the battery interior from drawing additional oxygen from the exterior atmosphere of the battery into the battery casing. If additional oxygen was drawn into the battery interior by the vacuum pressure created in the battery, the oxygen would continue to recombine with the material of the negative plate, which would continue to create a vacuum pressure in the battery interior that would continue to draw atmospheric oxygen into the battery casing. This continuing process would discharge the negative plates, and result in a premature failure of the battery.

The pressure relief valve 12 also functions to relieve increased gas pressure in the battery casing interior. During charging of the battery, a certain amount of the energy going into the battery causes electrolysis of the water content of the electrolyte, which generates oxygen gas at the positive plates and hydrogen gas at the negative plates of the battery. When the battery is over charging due to a mistaken charging procedure, a charger malfunction, or other incorrect charging procedures, a large amount of gas volume can be generated in the battery interior, resulting in a substantial increase in the gas pressure in the battery casing. The increased gas pressure in the battery interior is transmitted through the fill tube opening 16 and acts against the interior surfaces of the valve top wall 22 and the valve sidewall 24. The gas pressure causes the sidewall 24 to flex radially outwardly, separating the sidewall 24 from the fill tube 14 and allowing the gas pressure to escape from the battery interior. After the gas pressure is reduced, the resiliency of the sidewall 24 causes the sidewall to reestablish a sealing contact with the exterior of the fill tube 14. Because the rubber like material of the valve sidewall 24 is instantly resealable when the gas pressure is reduced, the gas pressure can be repeatedly vented from the battery casing interior when necessary.

Prior art battery pressure relief valves are disadvantaged in that the rubber or rubber-like resilient material of the cap 12 has been observed to have a tendency to stick to the fill tube 14 when the fill tube is constructed of a plastic or plastic-like material. The sticking of the cap sidewall 24 to the battery fill tube 14 usually occurs after the valve 12 has been mounted on the fill tube 14 for an extended period of time. To separate the cap 12 from the fill tube 14 after the cap 12 has become stuck to the fill tube 14, the rubber-like material of the cap sidewall 24 must be peeled away from the plastic material of the battery fill tube 14.

This undesirable sticking of the cap sidewall 24 on the fill tube 14 can result in the gas pressure inside the battery casing increasing above the level of pressure that was originally intended to separate the cap 12 from the fill tube 14 to vent the battery interior. Due to the rectangular configurations of most battery casings, the battery casings are not good or reliable pressure vessels. The increasing gas pressure inside a battery casing that cannot be vented due to the valve sidewall 24 being stuck to the battery fill tube 14 could cause cracking of the battery casing before the valve is opened. A crack in the battery casing could also cause the acidic liquid of the battery to leak from the battery interior. This would destroy the usefulness of the battery, and could potentially be very destructive to the surrounding environment of the battery. In a worse case scenario, the leaking acidic liquid could lead to a fire or explosion.

Furthermore, when the seal is broken between the valve sidewall 24 and the battery fill tube 14 after sticking, the seal must be reliably reestablished to prevent oxygen in the atmosphere from entering into the battery interior and deteriorating the useful life of the battery. The peeling away of the valve sidewall 24 from the battery fill tube 14 can cause damage to the surface of the sidewall that engages with the fill tube. This can result in an ineffective seal being established between the sidewall 24 and the fill tube 14, which would allow oxygen of the atmosphere to enter the battery interior.

The performance of a battery pressure relief valve could be improved by a redesign of the valve that provides a reliable seal around the battery fill tube, where the contact area of the seal is reduced. This would reduce the level of gas pressure needed to open the valve, even where the valve has become stuck to the fill tube. The valve performance could also be improved by a redesign of the valve that facilitates venting of the gas pressure from the battery interior and reliably reestablishes sealing contact around the battery fill tube after the gas pressure has been vented.

### SUMMARY OF THE INVENTION

The battery pressure relief valve of the present invention is provided in three embodiments. The embodiments have slightly different structural configurations, but all perform the same functions. All of the embodiments of the pressure relief valve are constructed of flexible and resilient materials that that are typically used in the construction of battery pressure relief valves. In the description of the valve to follow, the valve is described as being employed on a valve-regulated lead acid (VRLA) battery. This is the preferred environment of the valve. However, it should be understood that the valve of the invention may be employed on other types of batteries.

The first embodiment of the relief valve is comprised of a cap having a circular top panel and a cylindrical sidewall. The sidewall extends downwardly from the periphery of the top panel. When viewed in cross-section, the sidewall appears bowed and first curves away from the periphery of the top panel as it extends downwardly from the top panel, and then curves inwardly as it extends to a bottom annular edge of the sidewall. The configuration of the sidewall is designed for the sidewall bottom edge to engage in sealing engagement around a fill tube of a battery casing. This reduces the contact area of the cap with the fill tube, and reduces sticking of the cap to the fill tube. The curved configuration of the sidewall spaces a majority of the sidewall interior surface outwardly from the fill tube. Thus, the majority of the sidewall interior surface is exposed to gas pressure exiting the battery interior through the fill tube.

An elongated stem extends downwardly from the interior surface of the cap top panel. The stem has exterior surface portions that are dimensioned to engage against the interior surface of the battery fill tube. The stem is also formed with a pair of grooves between the exterior surface portions. The grooves extend along the length of the stem from the stem top end to a bottom end of the stem. These grooves provide a venting flow path for gas pressure generated in the battery interior.

A pair of tabs are provided at the bottom end of the stem. The tabs are designed to extend beneath the fill tube interior surface and secure the valve stem in the fill tube, preventing the valve from being pushed off of the fill tube by gas pressure generated in the battery interior.

The second embodiment of the battery pressure relief valve is similar to the first embodiment in that it also comprises a cap and a stem. The cap has a circular top panel and a cylindrical sidewall that extends downwardly from the periphery of the top panel. However, the sidewall does not have the bowed cross-section configuration of the first embodiment. The sidewall is substantially straight as it extends downwardly to a bottom end edge of the sidewall. The sidewall is dimensioned so that its interior surface is spaced radially outwardly from the battery fill tube.

An annular lip is provided on the bottom of the sidewall interior surface. The annular lip projects inwardly and engages in sealing engagement with the battery fill tube. The reduced contact area of the lip with the fill tube reduces the sticking of the cap to the fill tube.

The second embodiment stem extends downwardly from the center of the cap top panel. The stem has a top end joined integrally to the top panel interior surface, and extends downwardly to a bottom end of the stem. The stem has a substantially cylindrical exterior surface that is dimensioned to be spaced inwardly from the interior surface of the battery fill tube.

A plurality of lobes project outwardly from the stem exterior surface. The lobes are spatially arranged around the stem, and are dimensioned to engage against the interior surface of the battery fill tube. The friction engagement of the lobes with the interior surface of the battery fill tube secures the pressure relief valve to the battery fill tube.

The spacings between the circumferentially spaced lobes provide groove flow paths for gas generated in the battery interior. The flow paths extend along the stem length to the interior surface of the cap sidewall that is spaced outwardly from the battery fill tube.

The third embodiment of the battery pressure relief valve is substantially the same as the second embodiment of the valve, except for a second annular lip that is provided on the bottom of the sidewall interior surface. The second annular lip provides an additional seal around the battery fill tube. The second, redundant seal around the battery fill tube provides further protection against oxygen of the atmosphere entering the interior of the battery and potentially deteriorating the battery's useful life should there be a scratch or a blemish in one of the seals. Apart from the second annular lip seal, the third embodiment of the battery pressure relief valve is substantially the same as the second embodiment of the valve. This third embodiment is the most preferred of the valve embodiments.

In each of the embodiments of the battery pressure relief valve described above, the stem functions to securely hold the battery relief valve on the battery fill tube. The majority of the interior surface of the cap sidewall is spaced outwardly from the fill tube. The area of contact between the sidewall and the fill tube is substantially reduced. Because all of the force of the resiliency of the sidewall acts on the reduced area of contact between the sidewall and the fill tube, the reduced area of contact is pressed tightly against the exterior surface of the fill tube by the resiliency of the sidewall. This causes the material of the sidewall that engages with the fill tube to deform into any blemishes or scratches in the sidewall or fill tube that could cause a leak between the sidewall and fill tube.

The majority of the sidewall interior surface area, except for the area contacting the fill tube, is subjected to any gas pressure that is generated in the battery interior. The increased area of the sidewall interior surface subjected to the increasing gas pressure, and the reduced area of contact between the sidewall and the fill tube, result in the gas pressure forcing the sidewall to flex radially outwardly away from the fill tube, even when the sidewall has become stuck to the fill tube. This disengages the sealing engagement of the sidewall from the battery fill tube, and vents the gas pressure from the battery interior. Because a reduced amount of gas pressure is needed to separate the sidewall from the fill tube, and because a reduced area of the sidewall engages around the fill tube, the likelihood that damage will be done to the sidewall surface as it is peeled from sticking to the fill tube is reduced.

In addition, the majority of the sidewall interior surface area that is spaced outwardly from the fill tube is subjected to any vacuum pressure produced in the battery interior. The vacuum pressure acting on the majority of the sidewall interior surface area pulls that area of the sidewall inwardly toward the fill tube, and thereby enhances the sealing engagement of the reduced area of contact between the sidewall and the fill tube.

All of the embodiments of the battery pressure relief valve described above provide the advantage of a stem that securely holds the valve on the battery fill tube, and a cap having a sidewall that seals around the battery fill tube without significantly sticking to the fill tube, and having an increased interior surface area that, when subjected to gas pressure, readily flexes outwardly to relieve the gas pressure.

### BRIEF DESCRIPTION OF THE DRAWINGS

Further features of the invention are set forth in the following detailed description of the preferred embodiments of the invention, and in the drawing figures wherein:

FIG. 1 is a side sectioned view of a prior art battery pressure relief valve mounted on a fill tube of a battery casing;

FIG. 2 is a bottom plan view of the prior art valve of FIG. 1;

FIG. 3 is a perspective view of the battery of the invention that employs the battery pressure relief valves of the invention;

FIG. 4 is a side elevation view of a first embodiment of the battery pressure relief valve of the invention;

FIG. 5 is a top plan view of the valve of FIG. 4;

FIG. 6 is a bottom plan view of the valve of FIG. 4;

FIG. 7 is a side cross-section of the valve of FIG. 4 taken along the line 7-7 of FIG. 6;

FIG. 8 is a side cross-section of the valve of in FIG. 4 taken along the line 8-8 of FIG. 6;

FIG. 9 is a side elevation view of a second embodiment of the battery pressure relief valve of the invention;

FIG. 10 is a top plan view of the valve of FIG. 9;

FIG. 11 is a bottom plan view of the valve of FIG. 9;

FIG. 12 is a side cross-section of the valve of FIG. 9 taken along the line 12-12 of FIG. 11;

FIG. 13 is a side cross-section view of the valve of FIG. 9 mounted on a battery fill tube;

FIG. 14 is a side cross-section view of the third embodiment of the battery pressure relief valve of the invention; and,

FIG. 15 is a side cross-section view of the valve of FIG. 14 mounted on a battery fill tube.

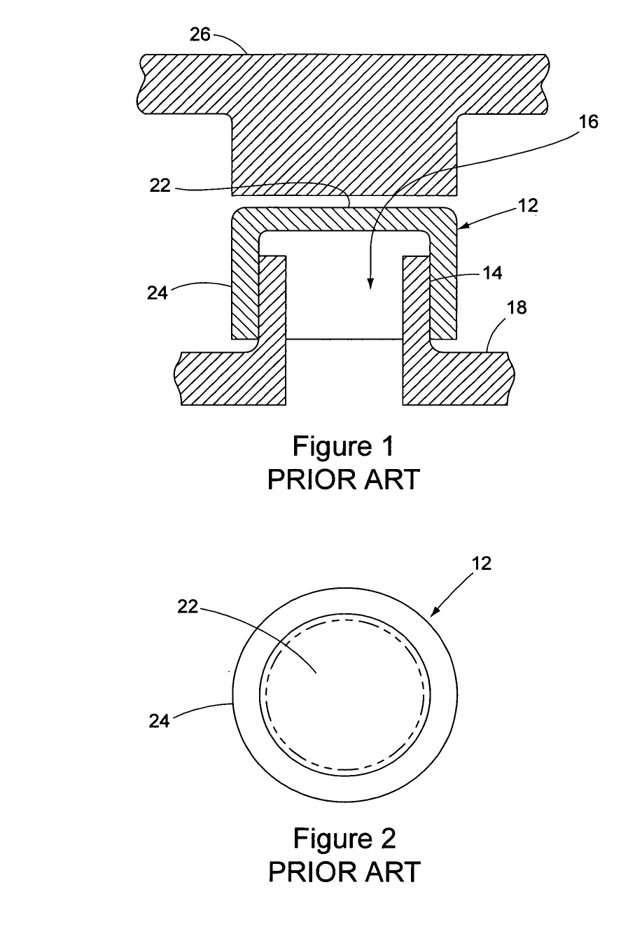

### DETAILED DESCRIPTION OF THE PREFERRED EMBODIMENT

As state earlier, the battery pressure relief valve of the invention is provided in three embodiments that function in the same manner, but have slightly different structural configurations. All of the embodiments are constructed of materials that are typically employed in the construction of battery relief valves. The materials give the embodiments of the relief valve resiliently flexible characteristics.

In the descriptions of the battery relief valves to follow, words such as “top”, “bottom”, and “downwardly” are used. These words should not be interpreted as requiring that the relief valves of the invention be used in any one orientation. The words are used to describe the component parts of the valves as shown in the orientation of the valves in the drawing figures. The valves could be used in orientations other than those shown in the drawing figures, and therefore these words should not be interpreted as limiting the valves to any particular orientation.

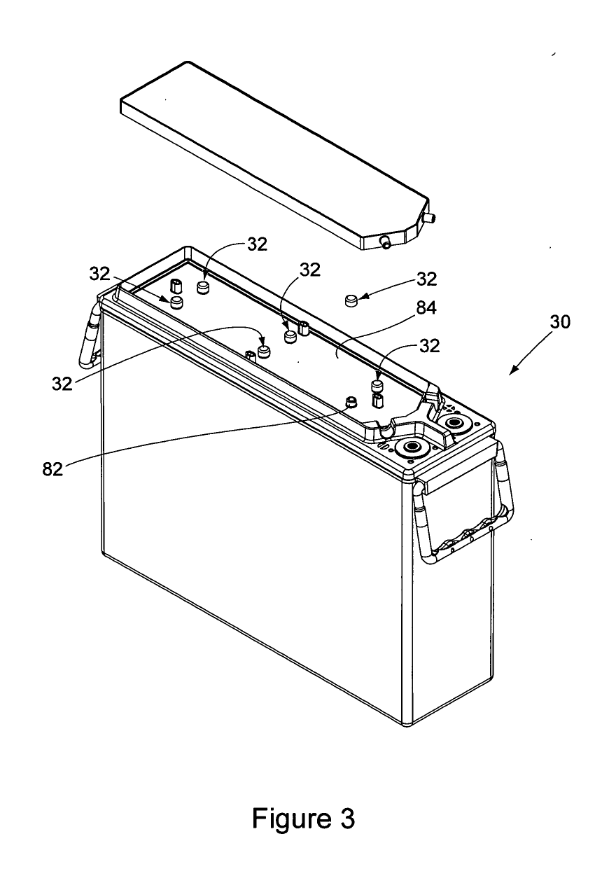

In the preferred embodiments of the relief valves of the invention, the valves are employed in sealing a fill tube on a valve-regulated lead-acid (VRLA) battery 30 of the type shown in FIG. 3. However, valves constructed in accordance with the invention could be used on other types of batteries.

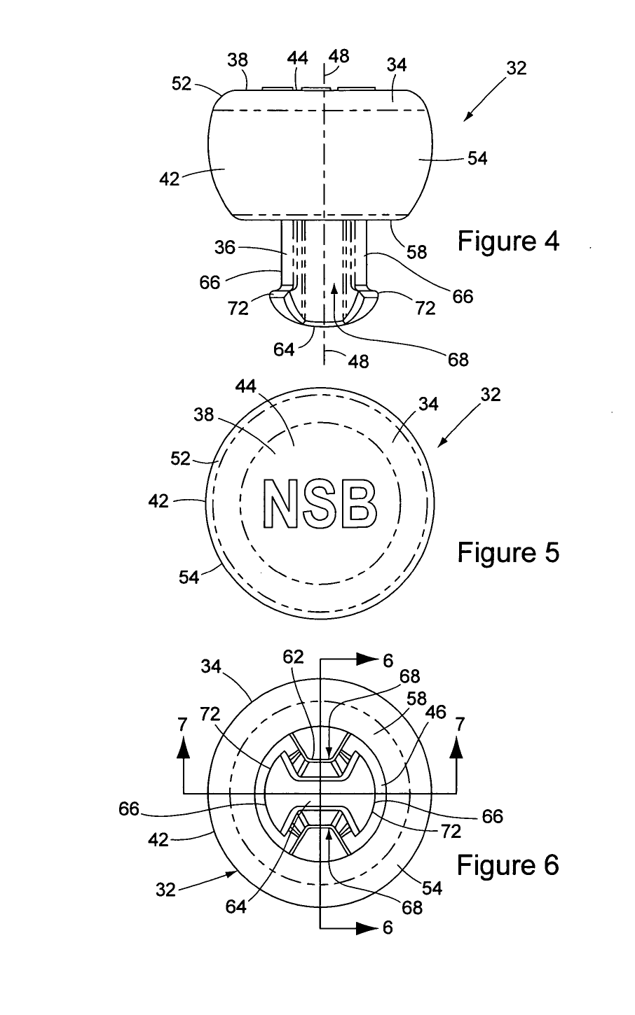

The first embodiment of the battery relief valve 32 is shown in FIGS. 3-8 and is comprised of a cap 34 and a stem 36. The cap 34 and stem 36 are integrally formed together, and the material of the valve 32 is consistent through the cap and stem.

The cap 34 is comprised of a cap top panel 38 and a sidewall 42. The top panel 38 is circular and has a top, exterior surface 44 and an opposite bottom, interior surface 46. The circular top panel 38 defines a center axis 48 of the valve that defines mutually perpendicular axial and radial directions. The top, exterior surface 44 and bottom, interior surface 46 are substantially parallel and extend radially outwardly to an outer periphery 52 of the top panel.

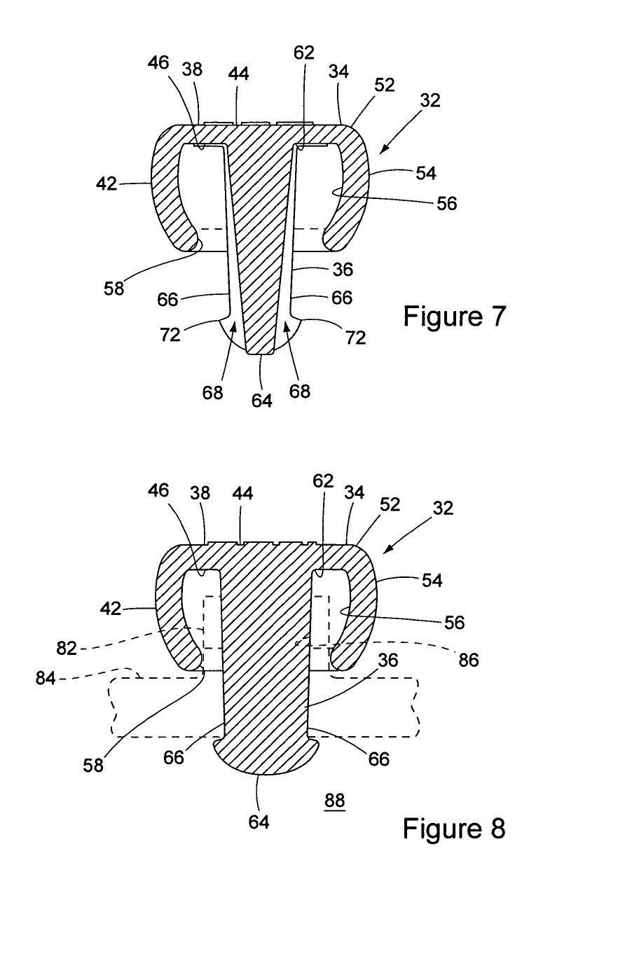

The cap sidewall 42 is generally cylindrical and extends downwardly from the top panel outer periphery 52. The sidewall 42 has opposite exterior 54 and interior 56 surfaces that, as shown in the cross-sections of FIGS. 7 and 8, first bow outwardly away from the top panel periphery 52, and then curve inwardly as the sidewall 42 extends downwardly from the top panel 38. The sidewall 42 extends downwardly to a bottom annular edge surface 58. The bottom annular edge surface 58 defines an annular lip that is dimensioned to engage in a sealing contact with a fill tube of a battery, as will be explained. The lip provides a reduced area of sealing contact between the valve sidewall 42 and the fill tube that can be easily separated by increasing battery gas pressure even after the contacting surfaces have become stuck together. The curved configuration of the sidewall 42 spaces a majority of the sidewall interior surface 56 radially outwardly from the fill tube.

The valve stem 36 extends axially downwardly from the top panel interior surface 46. The elongated stem 36 extends from a top end 62 of the stem, formed integrally with the top panel 38, downwardly to a bottom end 64 of the stem. The stem 36 extends downwardly beyond the bottom edge 58 of the cap sidewall 42.

The stem length has exterior surface portions 66 that generally define a cylinder, and are dimensioned to engage in friction engagement against the interior surface of a battery fill tube. These exterior surface portions 66 extend substantially the entire length of the stem.

The stem is also formed with a pair of axial grooves 68 that are recessed into the cylinder defined by the stem exterior surface portions 66. The pair of grooves 68 extend the entire length of the stem 36 and provide a venting flow path for gas pressure generated in the battery interior. As shown in FIG. 7, the flow path extends from the stem bottom end 64 along the grooves 68 to the top panel interior surface 46.

A pair of tabs 72 are provided at the bottom end 64 of the stem. The tabs 72 project radially outwardly from the pair of exterior surface portions 66 of the stem. The tabs 72 are dimensioned to engage across the fill tube interior surface and secure the valve stem 36 in the fill tube, preventing the valve from being pushed off of the fill tube by gas pressure generated in the battery interior.

FIG. 8 shows a dashed line representation of a battery fill tube 82 projecting from a wall 84 of a battery casing. The fill tube 82 has a cylindrical interior surface 86 that surrounds an opening of the fill tube that communicates the battery interior 88 with the exterior environment of the battery.

FIG. 8 also shows the first embodiment of the battery pressure relief valve 32 inserted into the battery fill tube 82. The valve stem 36 extends through the fill tube 82 with the stem exterior surface portions 66 engaging against the fill tube interior surface 86. The tabs 72 at the bottom of the stem 36 engage across the fill tube interior surface 86 and secure the valve 32 to the fill tube 82. The cap top panel 38 extends across the opening of the fill tube 82, and the cap sidewall 42 extends downwardly over the fill tube 82. The sidewall annular bottom edge 58 engages in sealing contact around the battery fill tube 82.

The sidewall bottom edge 58 functions as a narrow annular lip seal that engages around the battery fill tube 82 and seals the battery interior from the exterior atmosphere of the battery. The area of contact of the bottom edge 58 around the battery fill tube 82 is significantly reduced from the area of contact between the prior art cap sidewall 24 and the battery fill tube 14. As a result, the tendency of the cap sidewall 42 to stick to the battery fill tube 82 is significantly reduced, and the sidewall 42 will easily separate from the fill tube 82 when subjected to increasing gas pressure from the interior of the battery.

With the valve 32 assembled to the battery fill tube 82, the grooves 68 along the stem 36 vent the battery interior 88 to the space outside the battery fill tube 82 that is surrounded by the cap sidewall 42. When gas pressure is generated in the battery interior 88, the pressure is transmitted through the grooves 68 to the spacing between the fill tube 82 and the cap sidewall 42. The increased gas pressure acts against the sidewall interior surface 56, causing the sidewall 42 to flex radially outwardly from the valve stem 36. This flexing of the sidewall 42 causes the reduced contact area of the sidewall bottom edge 58 to separate from the battery fill tube 82, thereby venting the gas pressure to the exterior of the battery. When the pressure is removed, the resiliency of the sidewall 42 allows the sidewall to flex back to its at rest position shown in FIG. 8, where the sidewall bottom edge 58 once again engages in sealing engagement around the fill tube 82.

The reduced area of contact between the sidewall bottom edge 58 and the battery fill tube 82 causes the resilient force of the sidewall to be concentrated in a smaller area of engagement between the sidewall and the fill tube. Thus, the resilient force of the sidewall presses inwardly on the sidewall bottom edge 58 causing the sidewall bottom edge to press tightly and deform against the exterior surface of the battery fill tube 82. This ensures that the material of the sidewall bottom edge 58 will deform into any blemish or imperfection in the surface of the sidewall or fill tube that could potentially cause a leak.

Although the gas pressure also acts against the cap top panel interior surface 46, a majority of the pressure acts against the sidewall interior surface 56. The engagement of the tabs 72 across the fill tube interior surface 86 resists the gas pressure acting on the top panel interior surface 56 forcing the valve 32 out of the fill tube 82. This keeps the valve in place on the fill tube 82 until the cap sidewall 42 flexes outwardly to vent the gas pressure.

The majority of the area of the sidewall interior surface 56 that is spaced radially outwardly from the battery fill tube 82 is also acted on by negative pressure generated in the battery interior. This negative pressure generated by the battery pulls inwardly on the sidewall interior surface 56, and thereby enhances the sealing engagement between the sidewall bottom edge 58 and the battery fill tube 82.

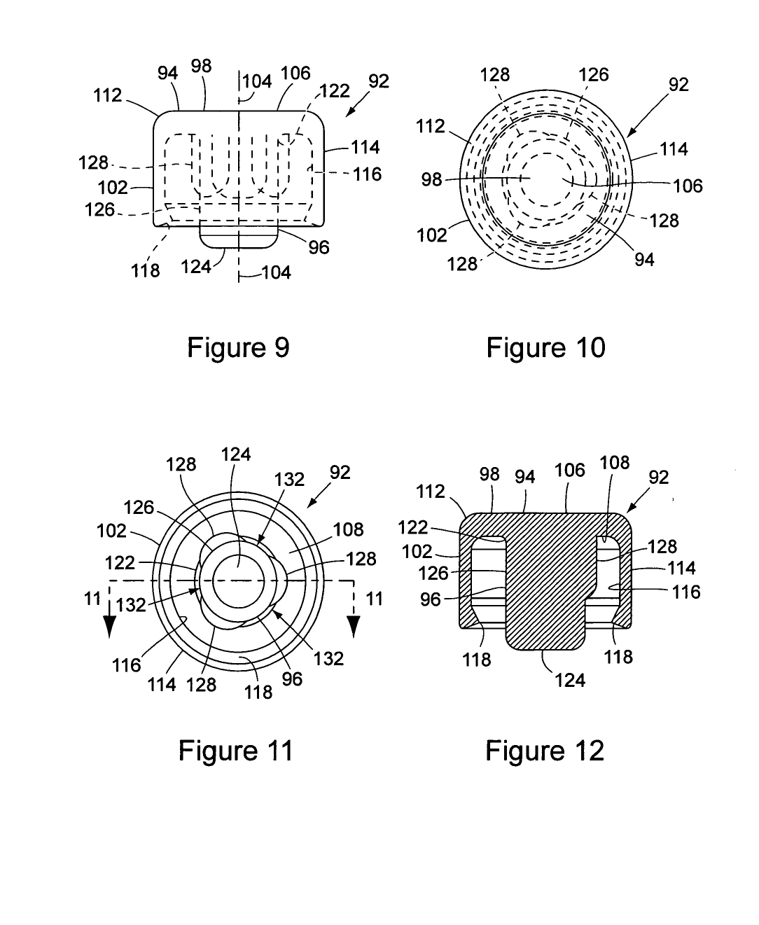

FIGS. 9-13 show the second embodiment of the battery pressure relief valve 92 of the invention. This embodiment is also comprised of a cap 94 and a stem 96 that are integrally formed of the same, flexible, resilient material.

Like the first valve embodiment, the cap 94 of the second embodiment includes a circular top panel 98 and a cylindrical sidewall 102. The circular configuration of the top panel 98 and the cylindrical configuration of the sidewall 102 define a center axis 104 of the valve. The top panel 94 has parallel exterior 106 and interior 108 surfaces that extend to an outer periphery 112 of the top panel.

The sidewall 102 has cylindrical exterior 114 and interior 116 surfaces that extend axially downwardly from the top panel periphery to a bottom annular edge 118 of the sidewall. The sidewall 102 differs from that of the previous embodiment in that the sidewall extends substantially straight downwardly from the top panel periphery 112. The sidewall exterior 114 and interior 116 surfaces are substantially parallel to each other and are parallel to the valve center axis 104. Adjacent the sidewall bottom edge 118, the sidewall interior surface 116 projects radially inwardly toward the stem 96 and forms the bottom edge 118 as an annular lip that is dimensioned to engage in sealing contact with the battery fill tube.

The stem 96 has a top end 122 that is formed integrally with the top panel interior surface 108. The stem extends downwardly beyond the sidewall 102 to the stem bottom end 124. FIG. 11 shows that the stem 96 has a substantially cylindrical exterior surface 126. The exterior surface 126 is dimensioned to be spaced radially inwardly from the interior surface of the battery fill tube.

A plurality of lobes 128 project radially outwardly from the stem exterior surface 126. Each lobe 128 extends axially across a portion of the stem exterior surface 126 from the stem top end 122. As shown in the drawing figures, the lobes 128 are joined integrally with the top panel interior surface 108, and extend downwardly along the stem 96 toward the stem bottom end 124, but stop before exiting from beneath the cap sidewall 102. The lobes 128 are spatially arranged around the circumference of the stem 96, and are dimensioned to extend radially outwardly a sufficient distance to engage against the interior surface of the battery fill tube. Three lobes 128 are shown in the drawing figures, but other numbers of lobes may be employed on the valve 92.

The circumferential spacings between adjacent lobes 128 provide grooves 132 or flow paths that extend axially along the stem 96. The grooves 132 allow gas generated in the battery interior to flow along the stem length to the interior surface 116 of the cap sidewall 102.

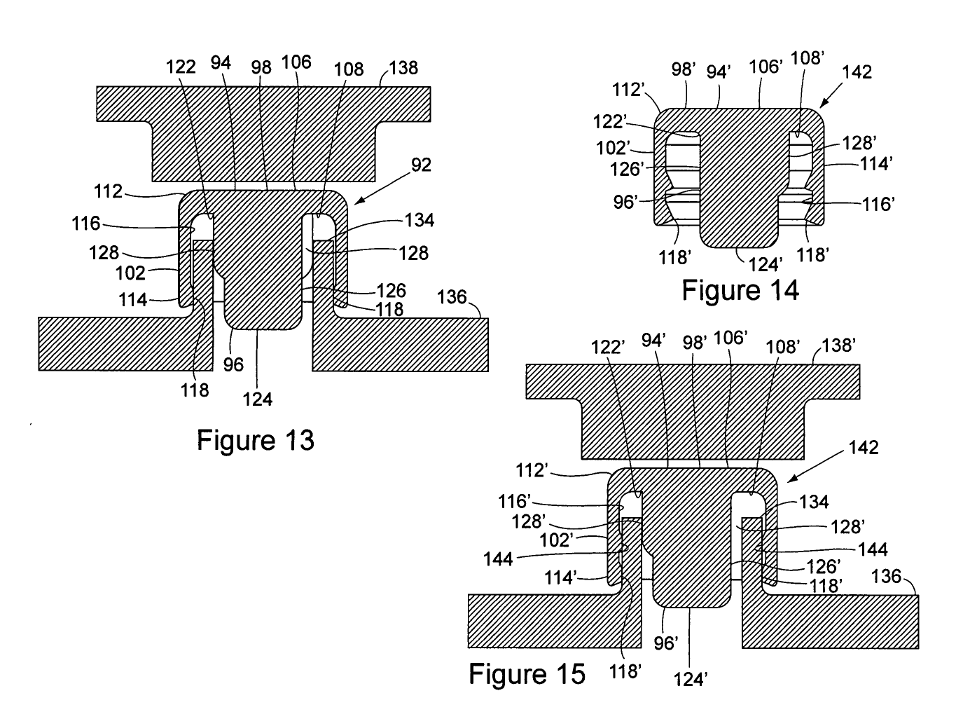

FIG. 13 shows a cross-section view of the second embodiment of the valve 92 secured to a fill tube 134 on a top wall 136 of a battery casing. A valve retainer/top cover 138 is shown positioned above the valve 92. The friction engagement of the lobes 128 with the interior surface of the battery fill tube 134 secures the pressure relief valve 92 to the battery fill tube. The top panel 98 of the cap extends over the fill tube opening. The cap sidewall 102 extends downwardly around the fill tube with the sidewall interior surface 116 spaced radially outwardly from the fill tube. The lip formed at the sidewall bottom edge 118 engages with the fill tube 134 and provides a seal around the fill tube.

As in the previously described embodiment, the reduced contact area of the sidewall bottom edge lip 118 with the fill tube 134 reduces the tendency of the valve sidewall 102 to stick to the fill tube. As a result, any sticking between the sidewall bottom edge 118 and the fill tube 134 will be quickly overcome by the radial flexing of the sidewall 102 caused by increasing gas pressure in the battery.

The resiliency of the sidewall extending around the sidewall bottom edge lip 118 functions to securely push the lip inwardly into engagement with the exterior surface of the fill tube 134, as in the previously described embodiment.

When gas pressure is generated in the interior of the battery, the grooves 132 defined between the lobes 128 on the stem 96 allow the gas pressure to be transmitted upwardly along the stem 96 to the interior of the cap 94. The increased gas pressure acts against the interior surface 116 of the cap sidewall 102, causing the sidewall 102 to flex radially outwardly away from the fill tube 134. The flexing of the sidewall 102 causes the lip at the sidewall bottom edge 118 to disengage from its sealing contact with the fill tube 134, allowing the gas pressure to be vented to the exterior environment of the battery. The reduced area of contact between the sidewall bottom edge lip 118 and the battery fill tube 134 allows the sidewall 102 to separate easily from the fill tube 134, even if the bottom edge 118 has become stuck to the fill tube. The reduced area of contact between the sidewall bottom edge 118 and the fill tube 134, if stuck together, will peel away from each other as the sidewall 102 expands radially outwardly due to the increasing gas pressure in the battery interior. In this manner, the second embodiment of the valve 92 functions in the same manner as the first described embodiment of the valve 32.

The interior surface 116 of the cap sidewall 102 functions in the same manner as the previously described embodiment when subjected to negative gas pressure generated in the battery. As explained earlier, the negative gas pressure acting on the sidewall interior surface 116 enhances the sealing engagement of the sidewall bottom edge lip 118 with the fill tube 134.

FIGS. 14 and 15 show the third, preferred embodiment of the battery pressure relief valve 142 of the present invention. The construction of the third embodiment of the valve 142 is substantially identical to that of the second embodiment of the valve 92, except for the addition of a secondary lip seal 144. Because the remaining construction of the third valve embodiment 142, and its method of use, are basically the same as the second described embodiment 92, the same reference numbers employed in describing the component parts and the method of using the second embodiment of the valve 92 are also employed in describing the third embodiment of the valve 142. These same reference numbers are followed by a prime (′). Because most of the component parts of the third embodiment of the valve 142 are the same as those of the second embodiment of the valve 92, those same component parts will not again be described in describing the third embodiment of the valve.

The third embodiment of the valve 142 differs from the second embodiment of the valve 92 in that it is provided with the secondary annular lip seal 144. As shown in FIGS. 14 and 15, the secondary seal 144 projects radially inwardly from the sidewall interior surface 116. The secondary annular lip 144 is also dimensioned to engage in sealing contact with the battery fill tube 134, as is the first described annular lip 118′ positioned at the bottom of the annular wall 102′.

Providing the valve 142 with a pair of interior annular lips 118′, 144 provides a redundant seal in the interior of the valve that engages around the exterior of the battery fill tube 134. The redundant seal protects against there being a blemish or scratch in one of the annular lip seals 118′, 144. The second seal without the scratch or blemish would prevent oxygen from the exterior environment of the battery from entering into the battery interior where it could potentially shorten the life of the battery. Apart from the provision of the secondary annular lip seal 144, the third embodiment of the valve 142 functions in substantially the same manner as the previously described second embodiment of the valve 142.

In variant but equivalent embodiments of the battery pressure relief valve, the annular lip seal could be provided as a radially projecting ridge extending around the circumference of the battery fill tube. The interior surface of the valve cylindrical side wall would basically be a smooth, cylindrical surface that would engage in sealing engagement with the annular lip seal on the fill tube. This would basically be the same concept of the embodiments of the invention described earlier. The sealing engagement surface between the interior surface of the valve sidewall and the exterior surface of the battery fill tube is reduced. In addition, a majority of the valve sidewall interior surface is exposed to both the positive pressure and the negative pressure produced in the battery interior. Thus, a valve and battery fill tube constructed in this manner would be an equivalent of the invention described above. Furthermore, an equivalent structure could include a valve having a stem with a cylindrical exterior surface that is inserted into a battery fill tube that has grooves formed into the interior surface of the fill tube. The grooves and the interior surface of the fill tube would function to allow the gas pressure to be transmitted through the grooves to the interior of the valve cap where the battery pressure will act on the interior surface of the cap sidewall. This is also seen as an equivalent variation of the embodiments of the relief valve described above.

All of the embodiments of the battery pressure relief valves described above provide the advantage of a stem that securely holds the valve on the battery fill tube, and a cap having a sidewall with an increased interior surface area subjected to battery gas pressure and a reduced area of sealing contact with the battery fill tube that, when subjected to gas pressure, flexes outwardly to relieve the gas pressure.

Although specific embodiments of the battery pressure relief valve have been described herein, it should be understood that modifications and variations of the valves may be arrived at without departing from the intended scope of the following claims.

1. A battery venting valve that is attached to a fill tube of a battery to cover over an opening of the fill tube, the valve comprising:
a stem having a length that extends between a top end and a bottom end of the stem, the stem length having a center axis that defines mutually perpendicular axial and radial directions, the stem having an exterior surface that is dimensioned for insertion of the stem into the opening of the fill tube;
a cap having a top panel on the stem top end, the top panel extending radially outwardly from the stem to an outer periphery of the top panel that is spaced radially outwardly from the stem top end; and
a cylindrical sidewall extending axially downwardly from the top panel periphery over at least a portion of the stem length, the sidewall having an interior surface that opposes the stem, the sidewall being flexible and resilient, whereby the sidewall will flex radially outwardly away from an at rest position of the sidewall relative to the stem when the sidewall interior surface is subjected to a fluid pressure, and the sidewall will return to the at rest position when the fluid pressure is removed.

2. The valve of claim 1, further comprising:
an annular lip on the sidewall interior surface, the lip having a circumference dimensioned for engaging the lip with the fill tube in the at rest position of the sidewall when the stem is inserted into the fill tube opening.

3. The valve of claim 2, further comprising:
the annular lip being one of a pair of first and second annular lips that are positioned axially side by side on the sidewall interior surface, each lip having a circumference dimensioned for engaging each lip with the fill tube in the at rest position of the sidewall when the stem is inserted into the fill tube opening.

4. The valve of claim 2, further comprising:
a majority of the sidewall interior surface being spaced radially outwardly from the lip.

5. The valve of claim 2, further comprising:
the sidewall extending axially from the top panel to a bottom edge of the sidewall; and
the lip being adjacent the sidewall bottom edge.

6. The valve of claim 1, further comprising:
the sidewall extending radially inwardly toward the stem as the sidewall extends axially from the top panel.

7. The valve of claim 1, further comprising:
the stem having exterior surface portions that are dimensioned to engage with the fill tube when the stem is inserted into the fill tube opening; and,
the stem having grooves recessed into the stem from the exterior surface portions, the grooves extending axially along the stem length.

8. The valve of claim 1, further comprising:
a battery having a fill tube with a fill tube opening; and
the stem extending into the fill tube opening with the top panel extending over the fill tube opening and the sidewall extending over and engaging with the fill tube.

9. A battery venting valve that is attached to a fill tube of a battery to cover over an opening of the fill tube, the valve comprising:
a stem having a length that extends between a top end and a bottom end of the stem, the stem length having a center axis that defines mutually perpendicular axial and radial directions, the stem having an exterior surface that is dimensioned for insertion of the stem into the opening of the fill tube;
a cap having a top panel on the stem top end, the top panel extending radially outwardly from the stem to an outer periphery of the top panel that is spaced radially outwardly from the stem top end; and
a cylindrical sidewall extending axially downwardly from the top panel periphery over at least a portion of the stem length, the top panel positioning the sidewall around the fill tube and spaced radially outwardly from the fill tube with there being a radial spacing between the fill tube and the sidewall when the stem is inserted into the fill tube opening.

10. The valve of claim 9, further comprising:
the sidewall having a cylindrical interior surface that opposes the fill tube when the stem is inserted into the fill tube opening, and a majority of the sidewall interior surface is spaced radially outwardly from the fill tube when the stem is inserted into the fill tube opening.

11. The valve of claim 10, further comprising:
an annular lip on the sidewall interior surface, the annular lip having a circumference dimensioned for engaging the lip with the fill tube when the stem is inserted into the fill tube opening.

12. The valve of claim 11, further comprising:
a majority of the sidewall interior surface being positioned between the top panel and the lip.

13. The valve of claim 10, further comprising:
a pair of annular lips on the sidewall interior surface, the pair of annular lips having circumferences dimensioned for engaging the pair of lips with the fill tube when the stem is inserted into the fill tube opening.

14. The valve of claim 11, further comprising:
the sidewall extending from the top panel to a bottom edge of the sidewall, and the lip being adjacent the sidewall bottom edge.

15. The valve of claim 9, further comprising:
the sidewall extending from the top panel to a bottom edge of the sidewall, and the sidewall extending radially inwardly toward the stem as the sidewall extends from the top panel toward the sidewall bottom edge.

16. The valve of claim 9, further comprising:
the stem having at least one axial groove recessed into the stem exterior surface, the stem being dimensioned to engage the stem exterior surface with an interior surface of the fill tube opening when the stem is inserted into the fill tube opening.

17. The valve of claim 9, further comprising:
a battery having a fill tube with a fill tube opening; and,
the stem extending into the fill tube opening with the top panel extending over the fill tube opening and the sidewall extending over and engaging with the fill tube.

18. A battery venting valve that is attached to a fill opening of a battery to cover over the fill opening, the valve comprising:
a cap having a top panel with an outer periphery that is dimensioned to cover over the fill opening;
a stem having a length that extends between a top end and a bottom end of the stem, the stem length having a center axis that defines mutually perpendicular axial and radial directions, the stem having an exterior surface that is dimensioned for insertion of the stem into the fill opening with the stem exterior surface engaging with a battery surface surrounding the fill opening to secure the stem in the fill opening; and
at least one groove recessed into the stem exterior surface and extending axially along the length of the stem, the groove providing fluid communication through the fill opening when the stem is inserted into the fill opening.

19. The valve of claim 18, further comprising:
the groove extending the entire length of the stem.

20. The valve of claim 18, further comprising:
at least one tab on the stem adjacent the stem bottom end, the tab being dimensioned to extend radially outwardly from the stem and across the battery surface when the stem is inserted into the fill opening.

21. The valve of claim 20, further comprising:
the tab being one of a pair of tabs on the stem on opposite sides of the stem axis; and,
the groove being one of a pair of grooves in the stem exterior surface on opposite sides of the stem axis.

22. The valve of claim 18, further comprising:
a cylindrical sidewall extending axially from the cap periphery toward the stem bottom end and over at least a portion of the stem length.

23. The valve of claim 18, further comprising:
the stem having a cylindrical exterior surface; and
a plurality of lobes on the stem projecting radially outwardly from the stem exterior surface, the lobes being circumferentially spaced from each other with the groove being positioned between a pair of adjacent lobes.

24. The valve of claim 23, further comprising:
the lobes being dimensioned to engage with the battery surface surrounding the fill opening to secure the stem in the fill opening.

25. The valve of claim 24, further comprising:
the stem cylindrical exterior surface being dimensioned smaller than the fill opening.

26. The valve of claim 18, further comprising:
a battery having a fill opening, the fill opening having an interior surface extending around the fill opening; and
the stem extending into the fill opening with the top panel extending over the fill opening and the stem exterior surface engaging with the fill opening interior surface securing the stem in the fill opening with the groove providing a fluid flow path through the fill opening.

27. A battery venting valve that is attached to a fill tube of a battery to cover over an opening of the fill tube, the valve comprising:
a cap having a circular top panel with a center axis that defines mutually perpendicular axial and radial directions, the top panel extending radially outwardly from the center axis to an outer periphery of the top panel; and
a cylindrical sidewall extending axially downwardly from the top panel periphery, the sidewall having a curved cross-sectional configuration that curves radially outwardly as the sidewall extends downwardly from the top panel periphery, and then curves radially inwardly as the sidewall extends downwardly to a bottom edge of the sidewall, the sidewall being flexible and resilient, whereby the sidewall will flex radially outwardly away from the center axis when the sidewall interior surface is subjected to a fluid pressure, and the sidewall will return radially inwardly when the fluid pressure is removed.

28. The valve of claim 27, further comprising:
an annular lip on the sidewall interior surface, the lip having a circumference dimensioned for engaging the lip with the fill tube when the cap is positioned over the fill tube opening.

29. The valve of claim 28, further comprising:
a majority of the sidewall interior surface being spaced radially outwardly from the lip.

30. The valve of claim 28, further comprising:
the lip being adjacent the sidewall bottom edge.

31. The valve of claim 27, further comprising:
a pair of annular lips on the sidewall interior surface, the pair of lips having circumferences dimensioned for engaging the pair of lips with the fill tube when the cap is positioned over the fill tube opening.

32. The valve of claim 27, further comprising:
a stem that extends downwardly from the cap top panel;
the stem having an exterior surface that is dimensioned to engage with the fill tube when the stem is inserted into the fill tube opening; and,
the stem having grooves extending axially along the stem.

33. The valve of claim 27, further comprising:
a battery having a fill tube with a fill tube opening; and
the cap being mounted on the fill tube with the top panel extending over the fill tube opening and the sidewall extending over and engaging with the fill tube.

34. A battery venting valve that is attached to a fill tube of a battery to cover over an opening of the fill tube, the valve comprising:
a cap having a circular top panel with a center axis that defines mutually perpendicular axial and radial directions, the top panel extending radially outwardly from the center axis to an outer periphery of the top panel;
a cylindrical sidewall extending axially downwardly from the top panel periphery, the top panel positioning the sidewall around the fill tube and spaced radially outwardly from the fill tube with there being a radial spacing between the fill tube and the sidewall when the cap is positioned over the fill tube opening; and,
an annular lip on the sidewall interior surface, the annular lip having a circumference dimensioned for engaging the lip with the fill tube when the cap is mounted on the fill tube.

35. The valve of claim 34, further comprising:
the sidewall having a cylindrical interior surface that opposes the fill tube when the cap is mounted on the fill tube, and a majority of the sidewall interior surface is spaced radially outwardly from the fill tube when the cap is mounted on the fill tube.

36. The valve of claim 34, further comprising:
the annular lip is one of a pair of annular lips on the sidewall interior surface, the pair of annular lips having circumferences dimensioned for engaging the lips with the fill tube when the cap is mounted on the fill tube.

37. The valve of claim 34, further comprising:
a majority of the sidewall interior surface being positioned between the top panel and the lip.

38. The valve of claim 34, further comprising:
the sidewall extending from the top panel to a bottom edge of the sidewall, and the lip being adjacent the sidewall bottom edge.

39. The valve of claim 34, further comprising:
a stem that extends downwardly from the cap top panel, the stem having an exterior surface that is dimensioned to engage with the fill tube when the stem is inserted into the fill tube opening.

40. The valve of claim 39, further comprising:
the stem having at least one axial groove.

41. The valve of claim 34, further comprising:
a battery having a fill tube with a fill tube opening; and,
the cap being mounted on the fill tube with the top panel extending over the fill tube opening and the sidewall extending over and engaging with the fill tube.

42. A battery having at least one fill tube surrounding an opening of the fill tube that communicates an interior volume of the battery with an exterior environment of the battery, the battery comprising:
a cap having a circular top panel with a center axis that defines mutually perpendicular axial and radial directions, the top panel extending radially outwardly from the center axis to an outer periphery of the top panel; and
a cylindrical sidewall extending axially downwardly from the top panel periphery, the sidewall having a curved cross-sectional configuration that curves radially outwardly as the sidewall extends downwardly from the top panel periphery, and then curves radially inwardly as the sidewall extends downwardly to a bottom edge of the sidewall, the sidewall being flexible and resilient, whereby the sidewall will flex radially outwardly away from the center axis when the sidewall interior surface is subjected to a fluid pressure, and the sidewall will return radially inwardly when the fluid pressure is removed.

43. The battery of claim 42, further comprising:
an annular lip on the side wall interior surface, the lip engaging with the fill tube.

44. The battery of claim 43, further comprising:
a majority of the sidewall interior surface being spaced radially outwardly from the lip and radially outwardly from the fill tube.

45. The battery of claim 42, further comprising:
a pair of annular lips on the sidewall interior surface, the pair of lips engaging in a sealing engagement around the battery fill tube.

46. The battery of claim 45, further comprising:
a majority of the sidewall interior surface being spaced radially outwardly from the pair of lips and being spaced radially outwardly from the fill tube.
